(19) United States
(12) Patent Application Publication
(10) Pub. No.: US 2025/0190656 A1
(43) Pub. Date: Jun. 12, 2025

(54) Polytopic Reduced-Order Model for Prediction, Estimation and Control of Partial Differential Equations

(71) Applicant: Mitsubishi Electric Research Laboratories, Inc., Cambridge, MA (US)

(72) Inventors: Saviz Mowlavi, Somerville, MA (US); Mouhacine Benosman, Boston, MA (US)

(73) Assignee: Mitsubishi Electric Research Laboratories, Inc., Cambridge, MA (US)

(21) Appl. No.: 18/538,664

(22) Filed: Dec. 13, 2023

Related U.S. Application Data
(60) Provisional application No. 63/606,696, filed on Dec. 6, 2023.

(51) Int. Cl. G06F 30/27

(52) U.S. Cl. CPC G06F 30/27

(57) ABSTRACT

A polytopic reduced-order model (ROM) generator is provided for a polytopic reduced-order model (ROM) used by an optimization controller in a heating, ventilation and air conditioning system. The physica model generator includes an interface circuit to receive a training dataset via a network connected to a simulation computer, a memory to store the polytopic ROM for predicting dynamics of airflow in the room, the training dataset, and instructions for calculating the parameters of the polytopic ROM, a processor to calculate the parameters of the polytopic ROM. The calculations include computing a global projection operation from high-dimensional state to reduced state, computing a global lifting operation from reduced state to high-dimensional state, constructing local reduced models of reduced state dynamics for each physical parameter value in the training dataset, and generating the polytopic ROM by combining a weighted average of the local reduced models with projection and lifting between reduced state and full state.

### TECHNICAL FIELD

The invention relates generally to modeling and control of systems governed by partial differential equations (PDEs), more specifically to applications including heating, ventilation and air conditioning (HVAC) airflow control using the PDEs.

### BACKGROUND

In systems governed by parametric partial differential equations (PDEs), the design of prediction, estimation and control algorithms is based on a reduced-order model (ROM) of the dynamics. Usually, this ROM does not include an explicit dependence on physical parameters, resulting in poor estimation and control performance when the system dynamics are strongly parameter-dependent. In the classical estimation and control literature for low-dimensional dynamical systems, parameter-dependent polytopic models have been proposed as a smooth interpolation between a finite number of local models corresponding to specific parameter values. The interpolation is realized through a weighted combination of the local models using parameter-dependent weights that obey certain properties. This polytopic approach, however, has not yet been applied to systems governed by PDEs, with online adaptation of the polytopic form to track the unknown physical parameters, e.g., geometry of the room, outside air temperature, or windows status in indoor airflow applications.

To that end, there exists a need for a method and a system control of systems governed by parametric partial differential equations (PDEs).

### SUMMARY

The embodiments of the invention provide a computer-implemented method for performing adaptive estimation and control of parametric systems governed by PDEs, which relies on a combination of classic ROM methods, polytopic modeling, and adaptive estimation and control. The proposed adaptive estimation and control approach has superior performance when compared with a classical robust approach that does not account explicitly for the unknown parameter.

According to some embodiments of the present invention, a polytopic reduced-order model (ROM) generator is provided for generating a polytopic reduced-order model (ROM) used by an optimization controller in a heating, ventilation and air conditioning (HVAC) system. The polytopic reduced-order model (ROM) generator may include an interface circuit configured to receive sensor measurements from sensors arranged in a room and a training dataset via a network connected to a simulation computer, wherein the training dataset includes solution trajectories of airflow temperature and velocity in the room for various physical parameter values and for various times series of setpoints given to the HVAC system; a memory configured to store the polytopic ROM for predicting dynamics of airflow in the room, the training dataset, and instructions for generating the polytopic ROM; and a processor configured to generate the polytopic ROM stored in the memory, wherein steps to generate the polytopic ROM comprise: computing a global projection operation from full state to reduced state, wherein the projection operation is independent of the physical parameter value; computing a global lifting operation from reduced state to full state, wherein the lifting operation is independent of the physical parameter value; constructing local reduced models of reduced state dynamics for each physical parameter value in the training dataset; and generating the polytopic ROM by combining a weighted average of the local reduced models with lifting from reduced state to full state, wherein weights in the weighted average depend on a difference between the true value of the physical parameter and its value in the corresponding local reduced model.

Further, another embodiment of the present invention can provide a computer-implemented method for generating a polytopic reduced-order model (ROM) used by an optimization controller in a heating, ventilation and air conditioning (HVAC) system. The computer-implemented method includes receiving sensor measurements from sensors arranged in a room and a training dataset via a network connected to a simulation computer, wherein the training dataset includes solution trajectories of airflow temperature and velocity in the room for various physical parameter values and for various times series of setpoints given to the HVAC system; computing a global projection operation from full state to reduced state, wherein the projection operation is independent of the physical parameter value; computing a global lifting operation from reduced state to full state, wherein the lifting operation is independent of the physical parameter value;
constructing local reduced models of reduced state dynamics for each physical parameter value in the training dataset; and generating the polytopic ROM by combining a weighted average of the local reduced models with lifting from reduced state to full state, wherein weights in the weighted average depend on a difference between the true value of the physical parameter and its value in the corresponding local reduced model.

### BRIEF DESCRIPTION OF THE DRAWINGS

The accompanying drawings, which are included to provide a further understanding of the invention, illustrate embodiments of the invention and together with the description to explain the principle of the invention. The drawings shown are not necessarily to scale, with emphasis instead generally being placed upon illustrating the principles of the presently disclosed embodiments.

FIG. 1A is a block diagram of an air-conditioning system according to one embodiment of the invention;

FIG. 1B is a schematic of an example of air-conditioning a room according to some embodiments of the invention;

FIG. 2 is a block diagram for the discerption of the projection of an infinite-dimensional model to a reduced-order model;

FIG. 3 is a block diagram for online fine-tuning of the reduced-order model using measurements from the system;

FIG. 4A is a block diagram for a method for constructing a polytopic reduced-order model of a parametric dynamical system offline, and using the polytopic reduced order model to control the system online, according to according to some embodiments of the present disclosure;

FIG. 4B shows an exemplary real-time hardware implementation of the polytopic reduced-order model (ROM) generator, according to embodiments of the present invention;

FIG. 5 is a block diagram for the architecture of the polytopic reduced-order model, according to according to embodiments of the present disclosure;

FIG. 6 is a block diagram for the construction of the polytopic reduced-order model, according to embodiments of the present disclosure;

FIG. 7 is a block diagram for an online control of the operation of the parametric dynamical system using the polytopic reduced-order model, according to according to some embodiments of the present disclosure;

FIG. 8 is a block diagram for an online estimator of the states and physical parameter of the system based on a dual approach;

FIG. 9 is a block diagram for an online estimator of the states and physical parameter of the system based on a joint approach; and

FIG. 10 shows an example of estimating a continuous airflow velocity field past a cylinder using limited velocity measurements from sensors in the wake of the cylinder and in the presence of parameter uncertainty.

While the above-identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

In describing embodiments of the disclosure, the following definitions are applicable throughout the present disclosure. A “control system” or a “controller” may be referred to a device or a set of devices to manage, command, direct or regulate the behavior of other devices or systems. The control system can be implemented by either software or hardware and can include one or several modules. The control system, including feedback loops, can be implemented using a microprocessor. The control system can be an embedded system.

An “air-conditioning system” or a heating, ventilating, and air-conditioning (HVAC) system may be referred to a system that uses a vapor compression cycle to move refrigerant through components of the system based on principles of thermodynamics, fluid mechanics, and/or heat transfer. The air-conditioning systems span a broad set of systems, ranging from systems which supply only outdoor air to the occupants of a building, to systems which only control the temperature of a building, to systems which control the temperature and humidity.

A “central processing unit (CPU)” or a “processor” may be referred to a computer or a component of a computer that reads and executes software instructions. Further, a processor can be “at least one processor” or “one or more than one processor.”

A “physical parameter” or “parameter” is a physical quantity that affects the behavior or the dynamics of the system that is being controlled. For example, in the case of HVAC airflow control in a room, the physical parameters may include the geometry of the room, the outside air temperature, the number and locations of occupants, the opening status of the windows and blinds, the number and types of objects in the room, etc.

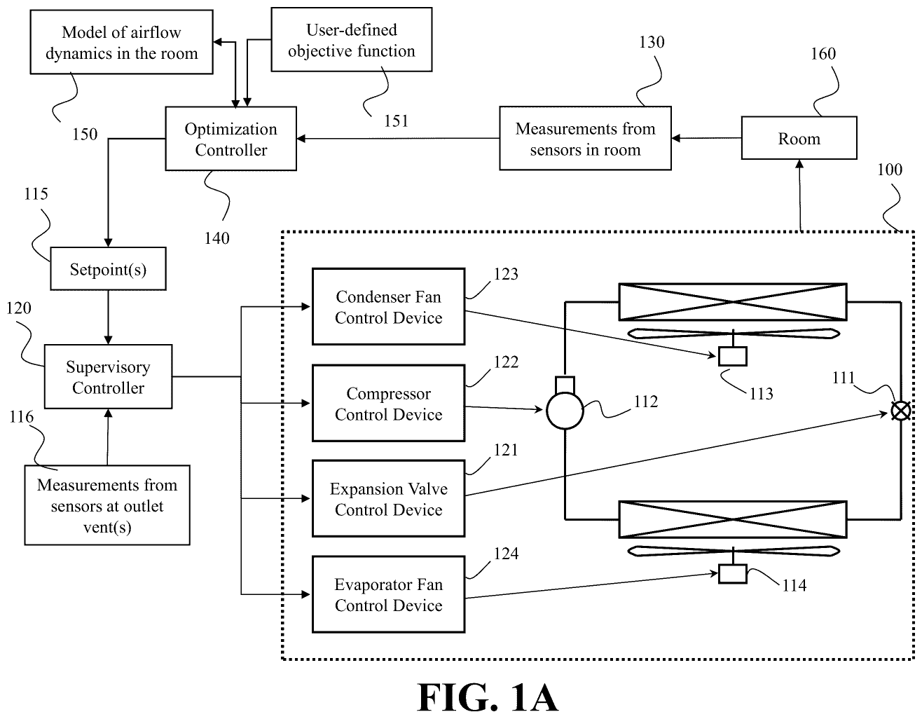

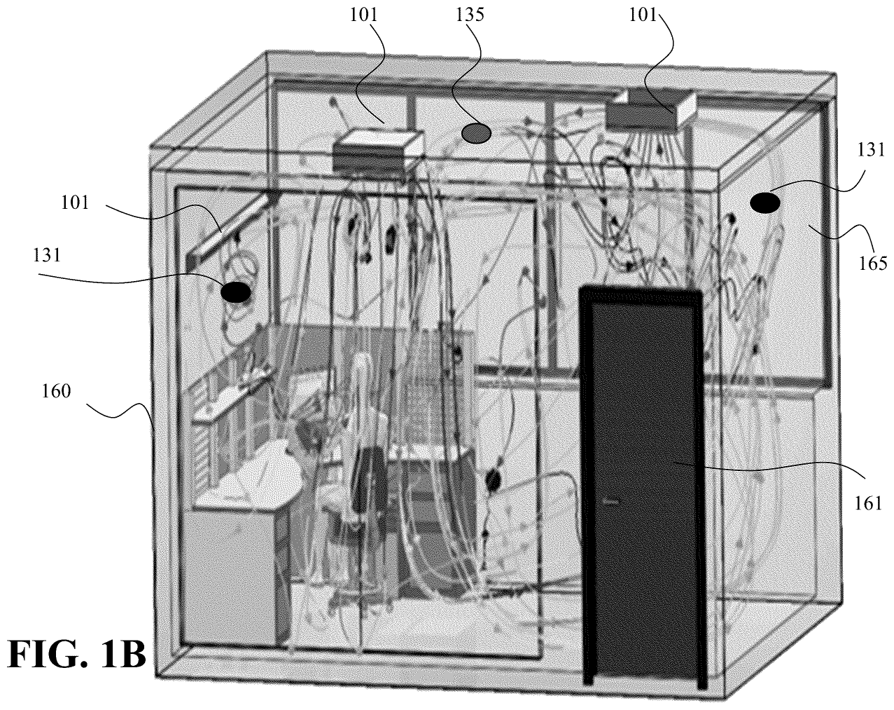

FIG. 1A shows a block diagram of an air-conditioning system 100 in a room 160, according to one embodiment of the invention. The system 100 can include one or a combination of components such as an evaporator fan 114 for adjusting airflow rate through a heat exchanger, a condenser fan 113 for adjusting airflow rate through another heat exchanger, a compressor 112 having an operating speed for compressing and pumping refrigerant throughout the HVAC system, and an expansion valve 111 for providing an adjustable pressure drop between a high-pressure portion and a low-pressure portion of the compressor. The system can be controlled by a supervisory controller 120 responsible for accepting one or multiple set-points 115. The set-points 115 are target values for airflow velocity, temperature, and direction at the outlet vent(s) of the air-conditioning system 100. The supervisory controller also receives readings from one or multiple airflow velocity and/or temperature sensors 116 placed at the outlet vent(s) of the air-conditioning system.

The supervisory controller outputs a set of control signals for controlling operation of the components 111, 112, 113, 114, such that the set-point values are achieved under all circumstances. This set of control signals is transformed by a set of control devices into specific control inputs for the corresponding components. For example, the supervisory controller is connected to a compressor control device 122, to an expansion valve control device 121, to an evaporator fan control device 124, and to a condenser fan control device 123. Other configurations of the air-conditioning system 100 are possible.

The set-points 115 are not directly assigned by the user; rather, they are calculated by an optimization controller 140 that receives readings (sensor measurements) from one or multiple sensors 130 placed at various locations in the room 160. The optimization controller 140 is also operatively connected to a model of the airflow dynamics 110 relating values of airflow velocity and temperature everywhere in the room with values of the setpoints 115. The goal of the optimization controller is to compute the set-points 115 to minimize a user-defined objective function 151, which encapsulates a metric of performance chosen by the user. In an embodiment, the objective function measures the deviation between the average temperature everywhere in the room and a desired value. In another embodiment, the objective function also measures the average velocity magnitude everywhere in the room.

FIG. 1B shows a schematic of an example of air-conditioning a room 160 according to some embodiments of the invention. In this example, the room 160 has a door 161 and at least one window 165. The airflow velocity and temperature of the room is controlled by an air-conditioning system, such as the system 100, through ventilation units 101. A set of sensors 130 is arranged in the room, which may include one or more velocity sensors 131 measuring airflow velocity at a given point in the room, one or more temperature sensors 135 measuring airflow temperature at a given point in the room. Other type of setting can be considered, for example a room with multiple HVAC units, or a house with multiple rooms.

The physical model of airflow dynamics is described by an infinite-dimensional parametric partial differential equation (PDE), because the airflow velocity and temperature are continuous functions of space, and their dynamics depend on physical parameters such as the outside air temperature, the geometry of the room, etc. One example of a parametric PDE model of airflow in a room are the Navier-Stokes equations with Boussinesq approximation. However, a parametric PDE model is too computationally expensive to be directly used by the optimization controller 140. Therefore, the parametric PDE model needs to be converted to a reduced-order (or low-dimensional) model (ROM). In FIG. 1, the model of airflow dynamics 150 is a ROM.

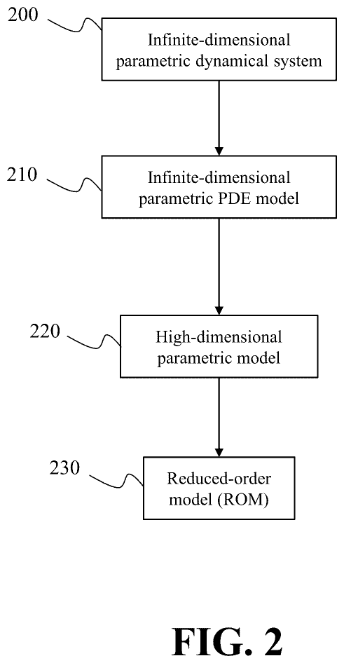

FIG. 2 is a block diagram for the discerption of the projection of an infinite-dimensional parametric PDE model 210 to a ROM 220. The PDE model describes the dynamics of an infinite-dimensional parametric dynamical system 200. For example, in the case of airflow dynamics in the room 160, the dynamical system 200 is the airflow in the room 160, and the parametric PDE model 210 are the Navier-Stokes equations with Boussinesq approximation. In other embodiments, other parametric PDE models describing different infinite-dimensional parametric systems can be considered, such as the heat conduction equation modelling heat transfer in a device, etc. The infinite-dimensional parametric PDE model 210 is first discretized into a high-dimensional parametric model 220, which is then converted to a reduced-order (or low-dimensional) model (ROM) 230. The ROM 230 provides an approximate but accurate enough description of the PDE model 210, while being much more computationally tractable. Going from the infinite-dimensional parametric PDE model 210 to the high-dimensional parametric model 220 involves spatial discretization techniques such as the finite difference method, finite volume method, etc, and temporal discretization techniques such as the Euler time-stepping scheme or the Runge-Kutta time-stepping scheme. Going from the high-dimensional parametric model 220 to the ROM 230 is possible using various existing methods. For example, a popular method is the dynamic mode decomposition (DMD), which results in a linear ROM 230.

However, most existing methods that transform the high-dimensional parametric model 220 into the ROM 230 carry along the uncertainty affecting the values of the physical parameters in the dynamical system 200 and its PDE model 210. For example, for the case of airflow in a room 160, many parameters that affect the dynamics of airflow velocity and temperature in the room can be uncertain, such as the geometry of the room, the number of people in it, the door being open or closed, the insulation of the walls, etc. To deal with this problem of uncertain physical parameters, we propose a computer-implemented polytopic reduced-order model (ROM) generator 401 that transforms the parametric PDE model 210 into a polytopic adaptive ROM 400, which enables the optimization controller 140 to perform online adaptive estimation and control of the system 200 with superior performance, lower processor usage, and lower energy consumption as compared with neglecting the uncertainty in the physical parameters.

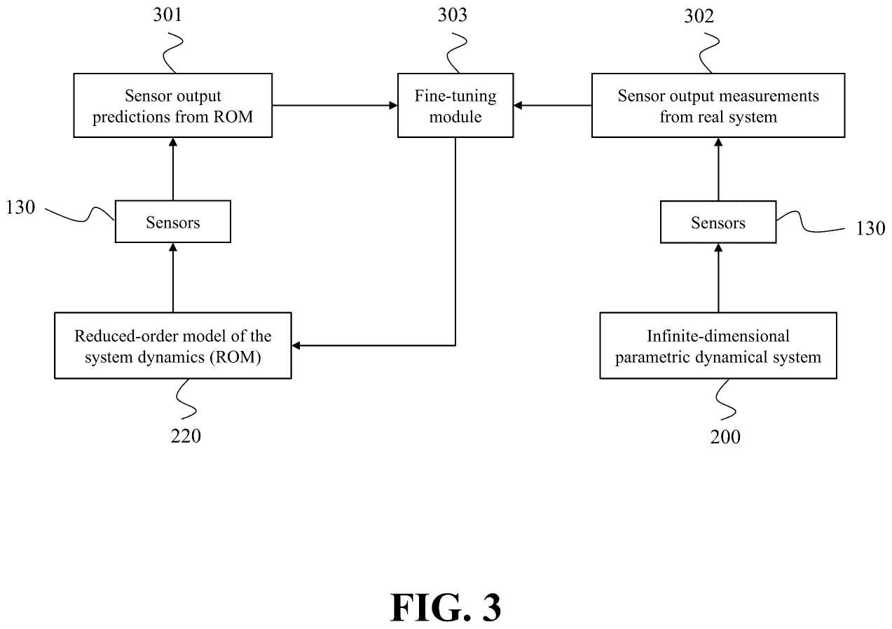

FIG. 3 is a block diagram for online fine-tuning of the ROM 230 using measurements from the system. In some embodiments, once the ROM 230 has been obtained, it can be run forward in time to obtain predictions 301 of the state at locations where sensors are placed in the real system 200. These values are then compared to online measurements 302 of the state at the same locations, from sensors placed in the real system 200. In step 303, the error between the prediction values 301 and the measurement values 302 is then used by the optimization controller 140 to fine-tune the ROM 230.

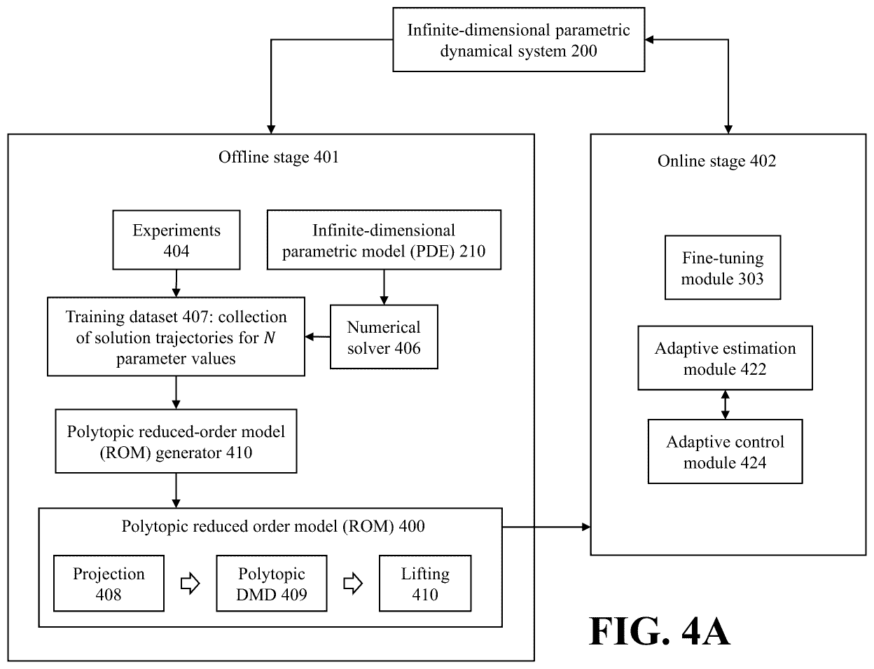

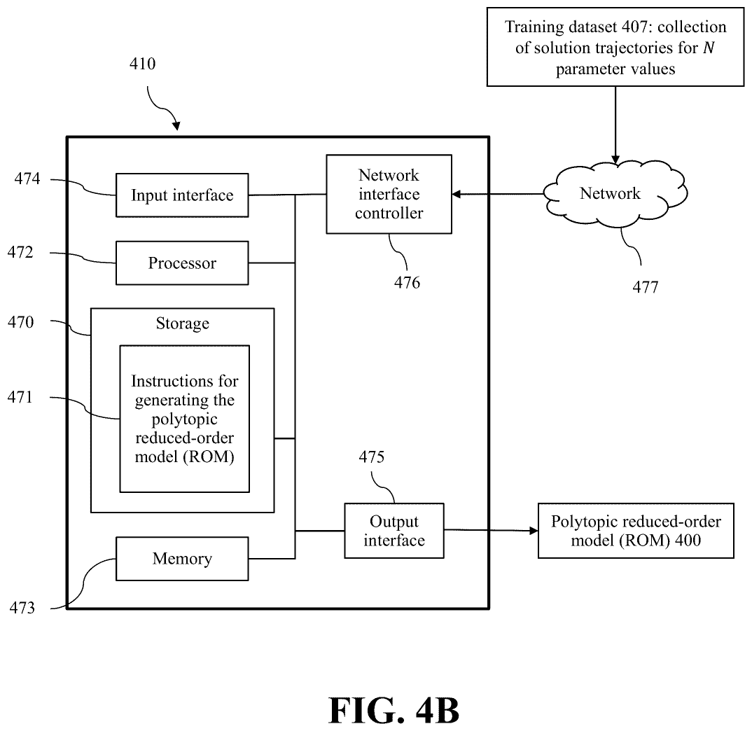

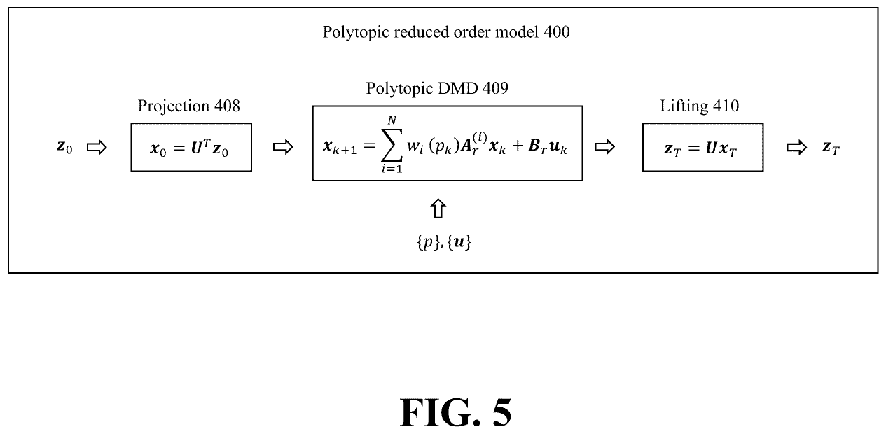

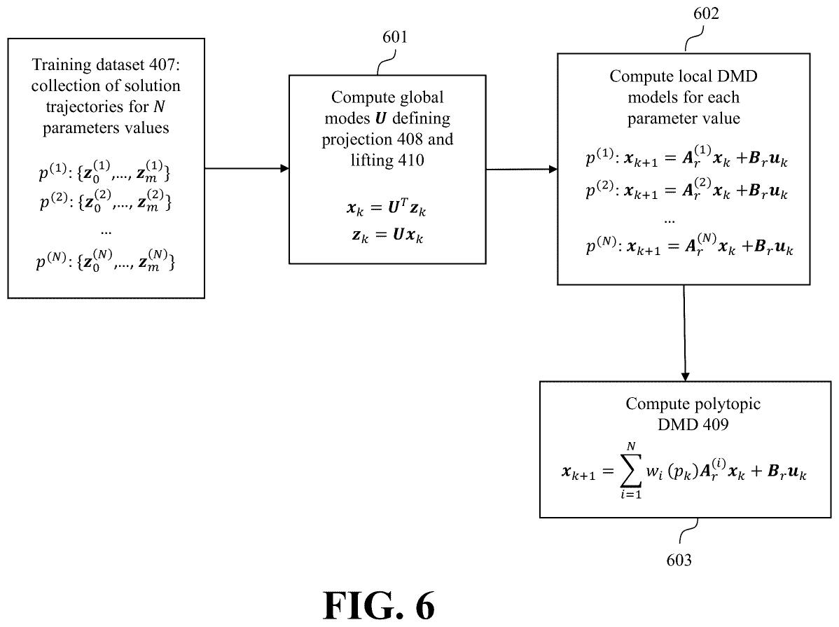

FIG. 4A is a flow diagram of a polytopic reduced-order model (ROM) generator 410 for constructing a polytopic ROM 400 of an infinite-dimensional parametric dynamical system 200 in an offline stage 401, then using the polytopic ROM 400 to perform fine-tuning 303 and/or adaptive estimation 422 and control 424 of the system during its online operation 402, according to some embodiments of the present disclosure. The hardware implementation of the polytopic ROM generator 410 is described in FIG. 4B, while the architecture and construction of the polytopic ROM are described in FIGS. 5 and 6. The polytopic ROM generator described in the present disclosure generates a ROM with improved accuracy over current state-of-the-art ROM generator methods by introducing dependence on physical parameters through a polytopic formulation. This leads to reduced processor usage and power consumption when executing adaptive estimation and control during online operation of the system.

For the example of HVAC airflow control described in some embodiments of the present disclosure, the airflow dynamics in the room 160 is the infinite-dimensional parametric dynamical system 200, the airflow dynamics model 150 is the polytopic ROM 400, and the optimization controller 140 includes the fine-tuning module 303, the adaptive estimation algorithm in module 422, and the adaptive control algorithm in module 424.

The offline stage 401 may further include an experiments module 404, an infinite-dimensional parametric PDE model 210 of the dynamics, a high-fidelity numerical solver module 406, and a training dataset 407 consisting of a collection of solution trajectories of the system 200 for different physical parameter values. Each solution trajectory includes an initial condition for the state of the system 200, a time series of control action values, and the resulting sequence of states of the system 200 at different time instances during the operation of the system 200 for a given physical parameter value. The solution trajectories in the training dataset 407 correspond to various physical parameter values, and they may be generated by performing experiments using the experiments module 404 or by using the high-fidelity numerical solver module 406 implemented on a simulation computer. For example, a solution trajectory for airflow in the room 160 might describe the velocity and temperature fields at different times as they evolve from an initial condition due to forcing from an HVAC system and for a given geometry of the room.

FIG. 4B shows an exemplary hardware apparatus implementing the polytopic reduced-order model (ROM) generator 410, according to embodiments of the present invention. The hardware apparatus include a storage 470 containing instructions 471 for generating the polytopic ROM. The hardware apparatus also includes a processor 472, a memory 473, an input interface 474, an output interface 475, and a network interface controller 476. The input interface 474 is configured to receive the training dataset 407 of solution trajectories using the network interface controller (NIC) 475 connected to a network 477. The memory 473 stores instructions that are executable by the processor 472, which is connected to one or more input and output devices. The processor 472 may execute the instructions 471 for generating the polytopic ROM from the training dataset 407. The output interface 475 is configured to transmit the generated polytopic ROM. In some embodiments, the input interface 474, the output interface 475, and the network interface controller 476 may be integrated as an interface circuit.

In the following, we will refer to the states of the system 200 as high-dimensional states, since each state is stored in the computer as a high-dimensional vector containing a discretized representation of the infinite-dimensional state of the system 200. For the example of airflow in the room 160, the high-dimensional state contains the velocity and temperature of the air at every node of a three-dimensional grid covering the entire volume of the room. On the other hand, the physical parameter, or parameter, is a low-dimensional vector that may include any physical quantity affecting the dynamics of the state. For instance, the physical parameter may include the length and width of the room, the temperature of the air outside the room, the insulation material of the walls, the opening status of windows and blinds, the number and location of occupants in the room, the number and types of objects in the room, etc. The high-dimensional state and the physical parameter are denoted zₖ and pₖ, respectively, with the subscript k indicating time dependence.

FIG. 5 is a schematic diagram of the architecture of the polytopic ROM 400, according to embodiments of the present disclosure. The ROM 400 includes a global projection algorithm 408, a polytopic DMD model 409, and a global lifting algorithm 410. The global projection algorithm and global lifting algorithm define inverse mappings from the high-dimensional state zₖ of the system 200 to a corresponding reduced state xₖ, and vice-versa. The ROM 400 uses three steps to predict the high-dimensional state z_{T} at final time given the high-dimensional state z₀ at initial time. First, the initial high-dimensional state z₀ is mapped to a corresponding reduced state x₀ using the projection algorithm 408. Given a time sequence of physical parameter values p₀, . . . , pₖ and control input values u₀, . . . , uₖ, the polytopic DMD model 409 is then used to evolve the reduced state x₀ to its value x_{T} at an arbitrary time T. Finally, the lifting algorithm 410 returns the high-dimensional state z_{T} corresponding to x_{T}.

More specifically, FIG. 6 is a schematic diagram illustrating the steps comprised in the polytopic reduced-order model (ROM) generator 410 to generate the polytopic ROM 400, according to embodiments of the present disclosure. Starting from a training dataset 407 of solution trajectories corresponding to N different physical parameter values, step 601 first computes the global modes defining the global projection algorithm 408 and the global lifting algorithm 410. The adjective ‘global’ refers to the fact that there is a single projection algorithm and a single lifting algorithm applying to states from all physical parameter values. For each physical parameter value, step 602 then applies the DMD to compute a local reduced model, or local DMD model, approximating the dynamics of the reduced state in the corresponding trajectory in the training dataset. Then, step 603 computes the polytopic DMD model as a weighted average of the local DMD models obtained in step 602, where each weight depends on the current value pₖ of the physical parameter. The resulting polytopic ROM 400 is therefore parametrized by the physical parameter. In the online stage 402, according to some embodiments, the method may fine-tune the polytopic ROM 400 using sensor measurements obtained from the online operation of the real system.

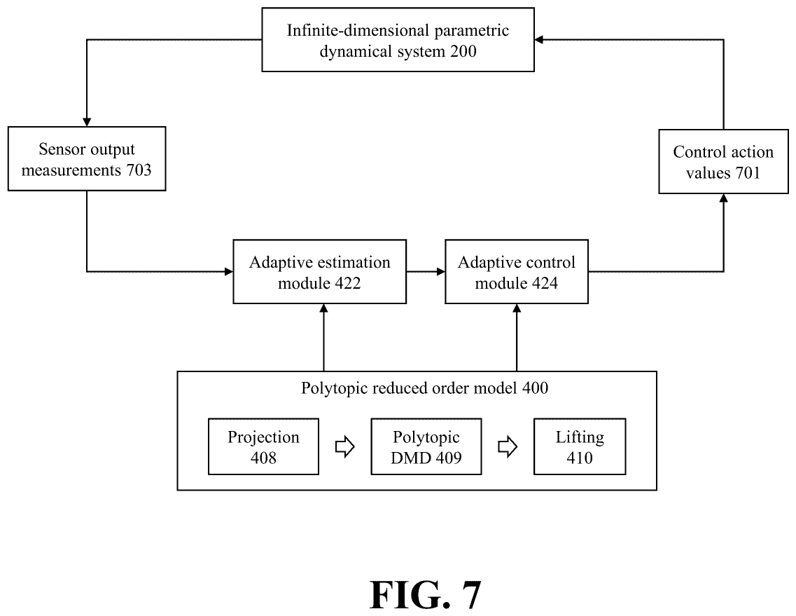

FIG. 7 is a block diagram illustrating online closed-loop control of an infinite-dimensional parametric dynamical system 200 using sensor measurements 703 of the state zₖ, according to some embodiments of the present disclosure. After the polytopic ROM 400 has been constructed in the offline stage 401, it may be used together with online sensor measurements 703 in a model-based adaptive estimation module 422 to estimate in real time the entire high-dimensional state zₖ of the system 200 and the value of its uncertain physical parameter pₖ. Using the physical parameter estimate, the polytopic ROM 400 can be adapted towards the model most representative of the system 200 in real time. Then, an adaptive control algorithm 424 may be used to compute in real time optimal control action values 701 to be given to the real system 200 so that the desired outcome defined by a control objective function is achieved.

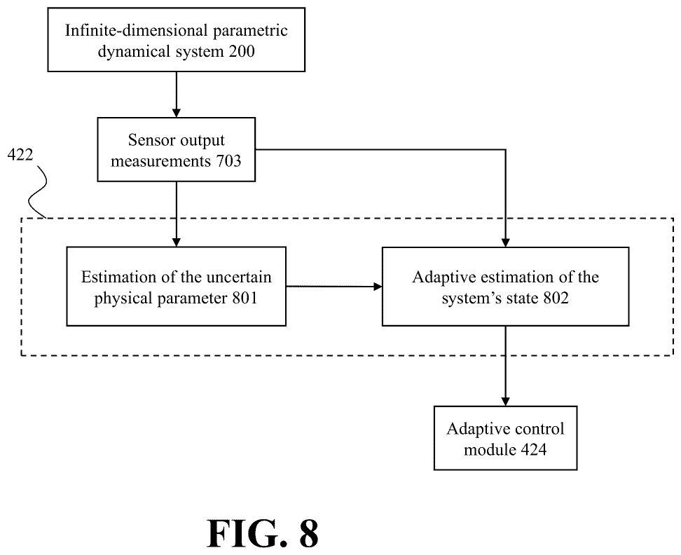

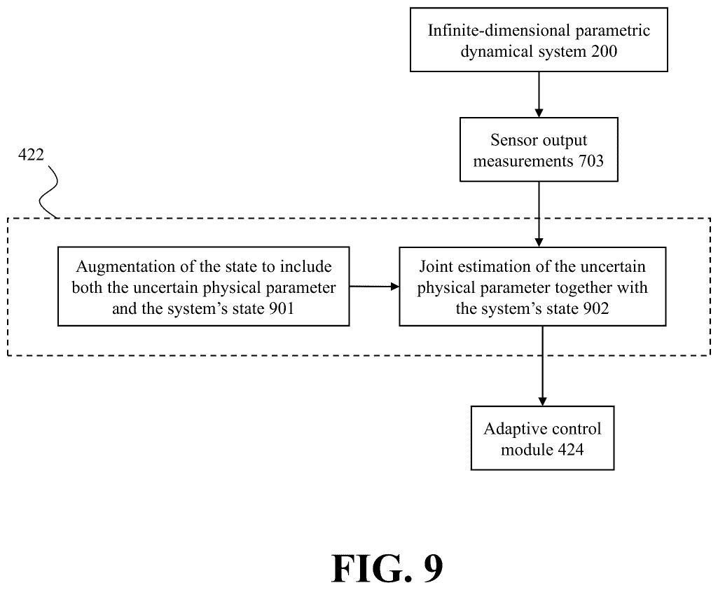

Thus, another point of the present invention concerns simultaneous estimation of the high-dimensional state zₖ and the physical parameter pₖ of the parametric system 200 from limited sensor measurements 703 of the state and in the presence of parameter uncertainty, using an adaptive estimator 422 based on the polytopic ROM 400. In one embodiment of the current invention, described in FIG. 8, we propose to perform dual estimation of the state and physical parameter by first estimating the uncertain parameter pₖ in step 801 with the sensor measurements 703, then using this parameter estimate with the polytopic ROM to estimate the state zₖ in step 802 with the sensor measurements 703. We call this estimation algorithm adaptive modular parameter-state estimation. In another embodiment of this invention, described in FIG. 9, we propose to estimate the uncertain parameter jointly with the state of the system by first concatenating the uncertain parameter together with the state vector of the system in step 901, then estimating this extended vector using the polytopic ROM and the sensor measurements 703. We call this estimation algorithm adaptive joint parameter-state estimation.

For example, for the case of airflow dynamics in the room 160, the high-dimensional state zₖ may contain the velocity and temperature of the air at every node of a three-dimensional grid covering the entire volume of the room. The physical parameter pₖ may include the length and width of the room, the temperature of the air outside the room, the insulation material of the walls, the opening status of windows and blinds, the number and location of occupants in the room, the number and type of objects in the room, etc.

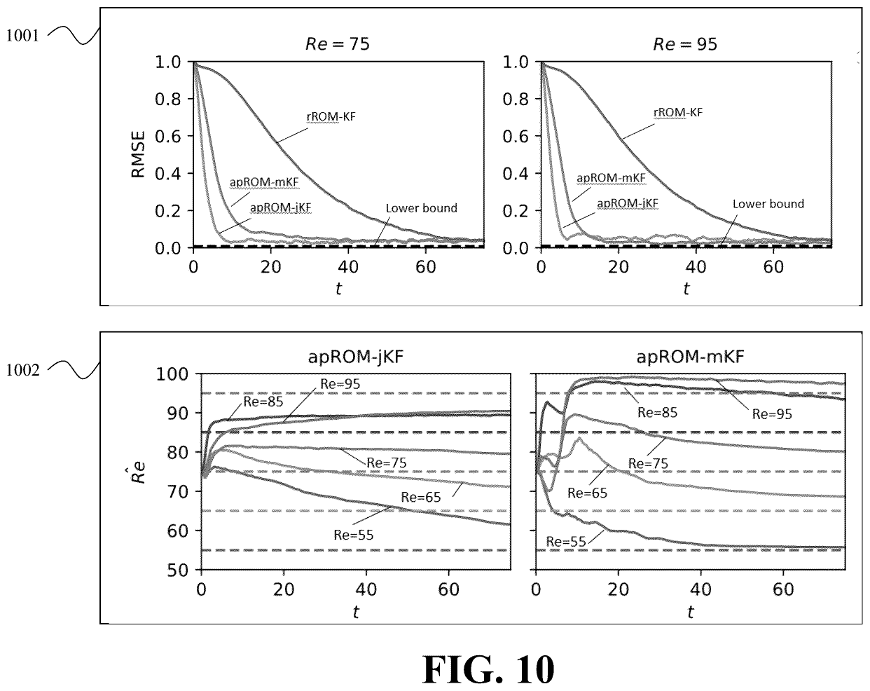

FIG. 10 shows an example of estimating the continuous airflow velocity field past a cylinder using limited velocity measurements from sensors in the wake of the cylinder and in the presence of parameter uncertainty. In this case, the infinite-dimensional system 200 is the airflow around the cylinder, the governing parametric PDE model 210 is the Navier-Stokes equations, the high-dimensional state zₖ contains the airflow velocity values at all nodes on a grid covering the domain, and the unknown physical parameter pₖ is the Reynolds number of the flow (which contains information on the viscosity of the fluid, the velocity of the incoming flow, and the diameter of the cylinder). In box 1001, the accuracy of the state estimates for zₖ obtained using the adaptive modular parameter-state estimation algorithm (apROM-mKF) and the adaptive joint parameter-state estimation algorithm (apROM-jKF), which are both based on the polytopic ROM, are compared with that obtained using a robust estimation algorithm (rROM-KF) based on a standard ROM that neglects the uncertainty in the physical parameter. The adaptive estimation algorithms outperform the robust estimation algorithm with superior estimation performance. Furthermore, box 1002 shows that the physical parameter estimates for pₖ obtained by the two adaptive estimation algorithms converge to the true physical parameter values, which can help an adaptive control algorithm find a better control policy. The robust estimation algorithm, on the other hand, does not produce an estimate for the physical parameter since it does not account for the latter.

Let us now put the steps described above into a more mathematical setting. We consider the state estimation problem for a parametric discrete-time high-dimensional dynamical system 220 described by

$${z}_{k + 1} = f ( {z}_{k} ; {p}_{k} ) ,$$

$${y}_{k} = h ( {z}_{k} , {n}_{k} ) ,$$

where zₖ∈Rⁿ and yₖ∈R^{m} are respectively the state and sensor measurements of the state at time k, pₖ∈[pₘᵢₙ, pₘₐₓ]⊂R is the uncertain physical parameter at time k, f: Rⁿ×R→Rⁿ is a nonlinear map from current state and parameter to next state, nₖ∈R^{m} is observation noise, and h: Rⁿ×R^{m}→R^{m} is a nonlinear map from current state and noise to measurement. In this study, we assume that the dynamical system 220 is obtained from a high-fidelity numerical discretization of a nonlinear PDE system 210, which typically leads to a high-dimensional state zₖ with at least a few hundred variables. Nonetheless, our proposed method is applicable to any high-dimensional nonlinear system.

The purpose of the computer-implemented method proposed therein is to formulate an estimation algorithm that solves the following problem: given a sequence of measurements {y₁, . . . , yₖ} from the dynamical system 220, estimate the high-dimensional state zₖ at current time k without knowledge of the physical parameter pₖ. The proposed method estimates both the state zₖ and the parameter pₖ by combining a polytopic reduced-order model (ROM) of the dynamics 220 with adaptive Kalman filtering methods. We now describe the ROM methodology followed by the construction of the filter.

To make online estimation practical despite the high-dimensionality of the dynamical system 220, the first step is to formulate a reduced-order model (ROM) 230 of the dynamics induced by 220. Inspired by previous work, we construct a ROM by using the proper orthogonal decomposition (POD) to project the high-dimensional state in an appropriate reduced-order subspace, followed by applying the dynamic mode decomposition (DMD) to obtain a linear model for the dynamics within the subspace. Our novelty lies in the way that we account for multiple dynamical regimes as the physical parameter pₖ varies, resulting in two new methodologies to construct a ROM in the presence of parameter uncertainty.

Since both the POD and DMD are data-driven, we begin by constructing a training dataset of trajectories obtained by solving the dynamical system 210 for a range of constant physical parameter values p specified by a finite set [symbol] ={p⁽¹⁾, . . . , p^{(q)}}⊂[pₘᵢₙ, pₘₐₓ], resulting in a concatenated collection of snapshots Zₜᵣₐᵢₙ={Z⁽ⁱ⁾}ᵢ₌₁^{q}, where each Z⁽ⁱ⁾={Z₀⁽ⁱ⁾, . . . , zₘ⁽ⁱ⁾} is a sequence of system states obtained by solving the dynamical system 210 for a specific value p⁽ⁱ⁾ ∈ [symbol] . We arrange the concatenated snapshots into two time-shifted matrices

$$X = \{ {z}_{0}^{( 1 )} , … , {z}_{m - 1}^{( 1 )} , … , {z}_{0}^{( q )} , … , {z}_{m - 1}^{( q )} \} ,$$

$$Y = \{ {z}_{1}^{( 1 )} , … , {z}_{m}^{( 1 )} , … , {z}_{1}^{( q )} , … , {z}_{m}^{( q )} \} .$$

To reduce the dimensionality of the system, we follow the POD methodology and perform a reduced-rank SVD of the data matrix X; that is, X≈UΣV^{T}, where U, V∈R^{n×r} are orthogonal, Σ∈R^{r×r} is diagonal, and r is the rank of the truncation. The columns of U, called the POD modes, contain the r most energetic spatial structures in the data (in an L₂ sense) and therefore span an energy-optimal subspace in which to project zₖ. The projection is defined by

xₖ=U^{T}zₖ,

yielding a reduced-order state xₖ representing the subspace coordinates, or modal amplitudes, of zₖ. Conversely, zₖ can be approximately recovered from xₖ as

zₖ≈Uxₖ,

where equality only holds when zₖ belongs to the range of U.

To find a model for the dynamics of xₖ, we employ the DMD, a purely data-driven algorithm that has found numerous applications in various fields. In its standard formulation, the DMD seeks a best-fit linear model of the dynamics for a single parameter p⁽ⁱ⁾ in the form of a matrix A∈R^{n×n} such that zₖ₊₁⁽ⁱ⁾≈Azₖ⁽ⁱ⁾) for all k, using the snapshots in Z⁽ⁱ⁾. Projecting this matrix to the columns of U results in a linear ROM xₖ₊₁≈Aᵣxₖ, where Aᵣ=U^{T}AU∈R^{r×r}. Such model requires much less computational resources to simulate when r«n. However, since this ROM is only trained using data from a single p⁽ⁱ⁾, it will produce inaccurate dynamics for other parameter values, in addition to the inherent approximation incurred by the linearity of the ROM.

Thus, we seek an adaptive polytopic ROM (apROM) that better approximates the dynamics corresponding to various pₖ∈[p₁, p₂] through an explicit dependence on pₖ. The parameter pₖ is assumed known when formulating the ROM, but it will later be estimated as part of the estimation algorithm. We first construct a library of matrices {A⁽¹⁾, . . . , A^{(q)}} by separately applying the DMD to each trajectory Z⁽ⁱ⁾, for all p⁽ⁱ⁾∈ [symbol] . Thus, for each p⁽ⁱ⁾ we compute A⁽ⁱ⁾∈R^{n×n} such that zₖ₊₁⁽ⁱ⁾≈A⁽ⁱ⁾zₖ⁽ⁱ⁾ for all k=0, . . . , m-1. The best-fit linear model is given by A⁽ⁱ⁾=Y⁽ⁱ⁾(X⁽ⁱ⁾)^{†}, where X⁽ⁱ⁾ and Y⁽ⁱ⁾ are given by

$${X}^{( i )} = \{ {z}_{0}^{( i )} , … , {z}_{m - 1}^{( i )} \} ,$$

$${Y}^{( i )} = \{ {z}_{1}^{( i )} , … , {z}_{m}^{( i )} \} .$$

We then construct an adaptive weighted average of these individual linear models as

Ā(pₖ)=Σᵢ₌₁^{q}wᵢ(pₖ)A⁽ⁱ⁾,
where the weights depend on pₖ through functions wᵢ(pₖ) that need to satisfy two properties: first, all wᵢ(pₖ)'s must always sum to one; second, each wᵢ(pₖ) must increase monotonically with decreasing |pₖ−p⁽ⁱ⁾|. Thus, a possible choice is to define the weights using a softmax function as

$${w}_{i} ( {p}_{k} ) = \frac{{e}^{{l}_{i} ( {p}_{k} )}}{{\sum }_{j = 1}^{q} {e}^{{l}_{j} ( {p}_{k} )}} ,$$

$${l}_{i} ( {p}_{k} ) = \frac{1}{ϵ + \vert {p}_{k} - {p}^{( i )} \vert / Δ p} ,$$

where Δp=pₘₐₓ−pₘᵢₙ, and ϵ>0 is a small number that prevents a division by zero and additionally serves as a control knob for the ‘sharpness’ of each weight function wᵢ(p) as pₖ approaches p⁽ⁱ⁾.

The relation between xₖ and zₖ and the orthogonality of U can then be applied to yield a linear discrete-time adaptive polytopic ROM of the form

$${x}_{k + 1} = {\overline{A}}_{r} ( {p}_{k} ) {x}_{k} + {w}_{k} ,$$

$${y}_{k} = {h}_{r} ( {x}_{k} , {v}_{k} ) ,$$

where Āᵣ(pₖ)=U^{T}Ā(pₖ)U∈R^{r×r} is an adaptive reduced state-transition model and hᵣ: R^{r}×R^{p}→R^{p} is the map from reduced state and noise to measurement, given by hᵣ(xₖ, vₖ)=h(Uxₖ, vₖ). The non-Gaussian process noise wₖ and observation noise vₖ account for the POD modes left out of the truncated SVD of X, as well as the error incurred by the linear approximation. The dependence of the dynamics on pₖ is accounted for through the weights wᵢ(pₖ), which push Āᵣ(pₖ) towards the matrix A⁽ⁱ⁾ corresponding to the parameter p⁽ⁱ⁾ that is closest to pₖ.

We now propose two computer-implemented methods to perform state estimation in the presence of parameter uncertainty: first, an adaptive modular parameter-state estimation algorithm that combines the adaptive polytopic ROM with two Kalman filters to estimate separately the state and the unknown parameter; second, an adaptive joint parameter-state estimation algorithm that combines the adaptive polytopic ROM with a single Kalman filter to estimate jointly the state and the unknown parameter.

Adaptive Modular Parameter-State Estimation (apROM-mKF)

To estimate both the reduced state xₖ and model parameter pₖ from the noisy measurement data, we first consider a modular dual parameter-state estimation algorithm inspired by the dual extended and unscented Kalman filters. In this approach, we simultaneously run two extended or unscented Kalman filters in parallel, one to provide a state estimate \hat{x}ₖ and one to provide a parameter estimate \hat{p}ₖ. The state-space representation for the dynamics model of the state is given by the adaptive polytopic ROM. As for the parameter, we assume that pₖ is time-dependent, so that the corresponding dynamics model can be described in state-space form by

$${P}_{k + 1} = {P}_{k} + {u}_{k} ,$$

$${y}_{k} = {h}_{r} ( {\overline{A}}_{r} ( {p}_{k} ) {x}_{k - 1} , {v}_{k} ) ,$$

where uₖ is white noise with small variance and hᵣ is the reduced measurement map introduced before. When running simultaneously the state and parameter filters, we use at each time step the state estimate in the parameter filter, and the parameter estimate in the state filter.
   Adaptive Joint Parameter-State Estimation (apROM-jKF)

The second approach we propose to estimate both the reduced state xₖ and model parameter pₖ is a joint parameter-state estimation algorithm inspired by the joint extended and unscented Kalman filters. In this approach, we construct a joint state vector x′ₖ=[xₖ^{T}, pₖ^{T}]^{T}. The state-space representation of the dynamics model for the joint state is given by a combination of the adaptive polytopic ROM and the parameter equation, that is,

$$[ \begin{matrix}{x}_{k + 1} \\ {p}_{k + 1}\end{matrix} ] = [ \begin{matrix}{\overline{A}}_{r} ( {p}_{k} ) {x}_{k} \\ {p}_{k}\end{matrix} ] + [ \begin{matrix}{w}_{k} \\ {u}_{k}\end{matrix} ] ,$$

$${y}_{k} = {h}_{r} ( {x}_{k} , {ν}_{k} ) ,$$

where uₖ is white noise with small variance and hᵣ is the reduced measurement map introduced before. We can then run an extended Kalman filter or unscented Kalman filter on the joint state vector to recover an estimation for both the state and the parameter.

The above description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Although the present disclosure describes the invention by way of examples of preferred embodiments, it is understood that various other adaptations and modifications may be made within the spirit and scope of the invention. Therefore, it is the object of the appended claims to cover all such variations and modifications as come within the true spirit and scope of the invention.

We claim:

1. A polytopic reduced-order model (ROM) generator for generating a polytopic reduced-order model (ROM) used by an optimization controller in a heating, ventilation and air conditioning (HVAC) system, comprising:
an interface circuit configured to receive sensor measurements from sensors arranged in a room and a training dataset via a network connected to a simulation computer, wherein the training dataset includes solution trajectories of airflow temperature and velocity in the room for various physical parameters values;
a memory configured to store the polytopic ROM for predicting dynamics of airflow in the room, the training dataset, and instructions for generating the polytopic ROM; and
a processor configured to generate the polytopic ROM stored in the memory, wherein steps to generate the polytopic ROM comprise:
computing a global projection algorithm from a high-dimensional state to a reduced state, wherein the projection algorithm is independent of the physical parameter value;
computing a global lifting algorithm from the reduced state to the high-dimensional state, wherein the lifting algorithm is independent of the physical parameter value;
constructing local reduced models of reduced state dynamics for each physical parameter value in the training dataset; and
generating the polytopic ROM by combining a weighted average of the local reduced models with the projection and lifting algorithms between the reduced state and the high-dimensional state, wherein weights in the weighted average depend on a difference between a true value of the physical parameter and its value in the corresponding local reduced model.

2. The polytopic reduced-order model (ROM) generator of claim 1, further comprising:
generating optimal setpoints for the HVAC system by applying an adaptive estimation and adaptive control algorithm to the polytopic ROM using sensor measurements; and
transmitting the optimal setpoints to a supervisory controller of the HVAC system.

3. The polytopic reduced-order model (ROM) generator of claim 2, wherein the supervisory controller controls at least one component of the HVAC system, wherein the HVAC system comprises components including:
an evaporator having a fan for adjusting an airflow rate through a heat exchanger; a condenser having a fan for adjusting the airflow rate through another heat exchanger;
a compressor having a speed for compressing and pumping refrigerant through the HVAC system; and
an expansion valve for providing an adjustable pressure drop between a high-pressure portion and a low-pressure portion of the compressor.

4. The polytopic reduced-order model (ROM) generator of claim 1, wherein the physical parameters include one or combination of outside air temperature, geometry of the room, number and types of objects in the room, opening status of windows, and opening status of blinds.

5. The polytopic reduced-order model (ROM) generator of claim 2, wherein the physical parameters include one or combination of outside air temperature, geometry of the room, number and types of objects in the room, opening status of windows, and opening status of blinds.

6. The polytopic reduced-order model (ROM) generator of claim 2, wherein the adaptive estimation and adaptive control algorithm is used to estimate the values of the high-dimensional state and physical parameter.

7. A computer-implemented method for generating a polytopic reduced-order model (ROM) used by an optimization controller in a heating, ventilation and air conditioning (HVAC) system, comprising:
receiving sensor measurements from sensors arranged in a room and a training dataset via a network connected to a simulation computer, wherein the training dataset includes solution trajectories of airflow temperature and velocity in the room for various physical parameter values;
computing a global projection algorithm from high-dimensional state to reduced state, wherein the projection algorithm is independent of the physical parameter value;
computing a global lifting algorithm from reduced state to high-dimensional state, wherein the lifting algorithm is independent of the physical parameter value;
constructing local reduced models of reduced state dynamics for each physical parameter value in the training dataset; and
generating the polytopic ROM by combining a weighted average of the local reduced models with the projection and lifting algorithms between the reduced state and the high-dimensional state, wherein weights in the weighted average depend on a difference between a true value of the physical parameter and its value in the corresponding local reduced model.

8. The computer-implemented method of claim 7, further comprising:
generating optimal setpoints for the HVAC system by applying an adaptive estimation and adaptive control algorithm to the polytopic ROM using the sensor measurements; and
transmitting the optimal setpoints to a supervisory controller of the HVAC system.

9. The computer-implemented method of claim 8, wherein the supervisory controller controls at least one component of the HVAC system, wherein the supervisory controller controls at least one component of the HVAC system, wherein the HVAC system comprises components including:
an evaporator having a fan for adjusting an airflow rate through a heat exchanger;
a condenser having a fan for adjusting the airflow rate through another heat exchanger;
a compressor having a speed for compressing and pumping refrigerant through the HVAC system; and
an expansion valve for providing an adjustable pressure drop between a high-pressure portion and a low-pressure portion of the compressor.

10. The computer-implemented method of claim 7, wherein the physical parameters include one or combination of outside air temperature, geometry of the room, number and types of objects in the room, opening status of windows, and opening status of blinds.

11. The computer-implemented method of claim 8, wherein the physical parameters include one or combination of outside air temperature, geometry of the room, number and types of objects in the room, opening status of windows, and opening status of blinds.

12. The computer-implemented method of claim 8, wherein the adaptive estimation and adaptive control algorithm is used to estimate the high-dimensional state and the physical parameters.
